(19) United States
(12) Patent Application Publication
(10) Pub. No.: US 2026/0059792 A1
(43) Pub. Date: Feb. 26, 2026

(54) DIE SIZE REDUCTION OF INTEGRATED CIRCUITS UTILIZING TRANSISTORS AS CURRENT SENSING ELEMENTS

(71) Applicant: Texas Instruments Incorporated, Dallas, TX (US)

(72) Inventors: Joseph Maurice Khayat, Bedford, NH (US); Weibing Jing, Beijing (CN); Henry L. Edwards, Garland, TX (US)

(21) Appl. No.: 18/815,548

(22) Filed: Aug. 26, 2024

(51) Int. Cl. H01L 29/78; H01L 27/088; H01L 29/06; H01L 29/08; H01L 29/10

(52) U.S. Cl. CPC H10D 30/65; H10D 62/107; H10D 62/158; H10D 62/393; H10D 84/83

(57) ABSTRACT

An example apparatus includes a metal-oxide-semiconductor (MOS), a first negative well, a second negative well, wherein the MOS is between the first negative well and the second negative well, a third negative well; and at least four negatively doped drift (Ndrift) regions, wherein the four Ndrift regions are between the second negative well and the third negative well.

### TECHNICAL FIELD

This description relates generally to transistors and, more particularly, to die size reduction of integrated circuits utilizing transistors as current sensing elements.

### BACKGROUND

A laterally-diffused metal-oxide semiconductor (LDMOS) is a planar double-diffused metal-oxide semiconductor field effect transistor (MOSFET). In some examples, an LDMOS is fabricated on p/p+ silicon epitaxial layers. The fabrication of an LDMOS often involves various ion-implantation and subsequent annealing cycles. For example, the drift region of an LDMOS may be fabricated using up to three ion implantation sequences in order to achieve the appropriate doping profile needed to withstand high electric fields. LDMOS MOSFETs are often used in switching power converters, amplifiers such as linear high-power amplifiers, radio frequency power amplifiers, etc.

### SUMMARY

For transistor die size reduction, an example apparatus includes a metal-oxide-semiconductor (MOS); a first deep negative well; a second deep negative well, where the MOS is between the first deep negative well and the second deep negative well. The apparatus includes a third deep negative well; and at least four negatively doped drift (Ndrift) regions, where the at least four Ndrift regions are between the second deep negative well and the third deep negative well. Other examples are described.

For transistor die size reduction, an example apparatus includes an epitaxial layer; a negatively doped drift (Ndrift) region in the epitaxial layer, a first negatively doped region in the Ndrift region, a second negatively doped region in the Ndrift region, a first field oxide in the Ndrift region and coupled to the first negatively doped region, a first pad oxide on the first field oxide and the Ndrift region and in contact with the second negatively doped region, and a second isolation layer on the Ndrift region and in contact with the second negatively doped region. Other examples are described.

For transistor die size reduction, an example apparatus includes a first laterally-diffused metal-oxide semiconductor (LDMOS) having a gate, a source, and a drain; a second LDMOS having a gate coupled to the gate of the first LDMOS and a source, and a first negatively doped drift resistor coupled to the source of the second LDMOS. Other examples are described.

### BRIEF DESCRIPTION OF THE DRAWINGS

FIG. 1 is a circuit diagram illustrating an example circuit for monitoring a current through a load.

FIGS. 2A and 2B illustrate a cross-sectional view of an example integrated circuit.

FIGS. 3A and 3B illustrate a cross-sectional view of an example integrated circuit.

FIG. 4 is a top view of a die including an integrated circuit.

FIGS. 5-7 are charts illustrating measured current flow through a main transistor and a sensing transistor circuit.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

In some current sensing circuitry, a series of MOSFETS (e.g., LDMOSs) are utilized to control a ratio of current through the series MOSFETS relative to a main source (e.g., main MOSFET). When combining a series of MOSFETs on a die, the individual MOSFETS must each be placed in a separate isolation tanks/wells to avoid shorting their integrated backgates. For example, a transistor may have a backgate that provides an additional gate on the body/substrate of the transistor. If multiple transistors are formed on a substrate, coupled in series, and not isolated from each other, the backgates of the multiple transistors with cause the multiple transistors to be shorted to each other. Accordingly, series MOSFETs utilize a large amount of physical space on a die.

Semiconductor designs described herein implement a circuit to emulate a series MOSFET (e.g., series LDMOS) structure. The described semiconductor design facilitates a series of semiconductor structures within an isolation tank/well while avoiding the short circuit condition of actual MOSFETs. According to examples described herein, the semiconductor structure includes a MOSFET (e.g., LDMOS) coupled in series with two or more semiconductors referred to herein as Ndrift resistors. The example Ndrift resistors are implemented similar to a MOSFET, but do not include a positively doped body region that is located in the center of the MOSFET. Accordingly, the Ndrift resistors do not include a source terminal that would result in shorting of multiple MOSFETs placed in the same isolation tank/well. Thus, multiple Ndrift resistors can be combined in a single isolation tank/well, which reduces the physical space of such a semiconductor. Utilizing a single MOSFET (e.g., LDMOS) in series with a plurality of Ndrift resistors provides a current flow that is similar to a current flow through a plurality of series-connected MOSFETs, but utilizes a much smaller footprint (e.g., by eliminating the need for negatively doped deep wells between each MOSFET or pair of MOSFETs).

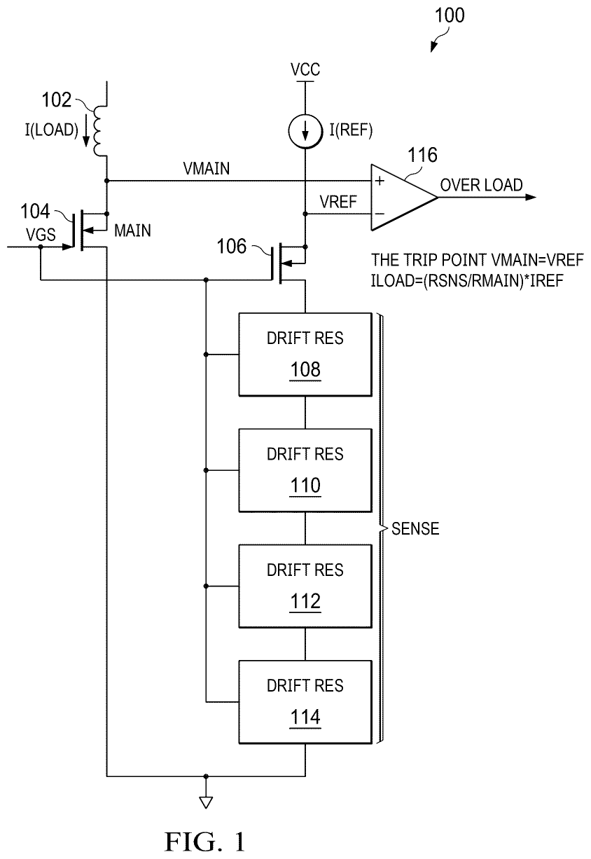

FIG. 1 is a circuit diagram illustrating an example circuit 100 for monitoring a current through a load. The example circuit 100 includes an example load 102, example first transistor 104, an example second transistor 106, an example first Ndrift resistor 108, an example second Ndrift resistor 110, an example third Ndrift resistor 112, an example fourth Ndrift resistor 114, and an example comparator 116.

The example load 102 is an inductive load. For example, the load may be a motor. Alternatively, the load 102 may be any type of load such as a resistive load, a capacitive load, etc.

The example first transistor 104 is a laterally-diffused metal-oxide semiconductor (LDMOS) transistor. Alternatively, any other type of semiconductor may be utilized. The example first transistor 104 includes a drain, a gate, and a source that is coupled to the body of the transistor. A gate voltage VGS is coupled to the gate of the first transistor 104 to regulate the current in the load 102. While the example transistor 104 is an N-channel transistor, the transistor 104 may alternatively be implemented by a P-channel transistor.

The example second transistor 106 is an LDMOS transistor. Alternatively, any other type of semiconductor may be utilized. The example second transistor 106 includes a drain, a gate, and a source that is coupled to the body of the transistor. A gate voltage VGS is coupled to the gate of the second transistor 106 to regulate the current from a reference source. While the example transistor 106 is an N-channel transistor, the transistor 104 may alternatively be implemented by a P-channel transistor.

The example first Ndrift resistor 108, the example second Ndrift resistor 110, the example third Ndrift resistor 112, and the example fourth Ndrift resistor 114 are semiconductors that are implemented similarly to the LDMOS transistor of the first transistor 104 and the second transistor 106, but do not include a body coupled to the source of the semiconductor. Accordingly, the Ndrift resistors 108-114 provide resistance characteristics that are similar to an LDMOS. According to the illustrated example, the combination of the transistor 106 and the Ndrift resistors 108-114 relative to the first transistor 104 implements a desired ratio (e.g., 100,000:1). Thus, instead of implementing a plurality of transistors (e.g., LDMOS) in series, the example circuit 100 includes the second transistor 106 in series with the plurality of Ndrift resistors 108-114. Further, because the Ndrift resistors 108-114 do not include a source-connected body, they can be included in a single isolation tank/well (e.g., a region that is isolated from other regions by isolating structures such as one or more wells) to reduce the physical space relative to a series of transistors.

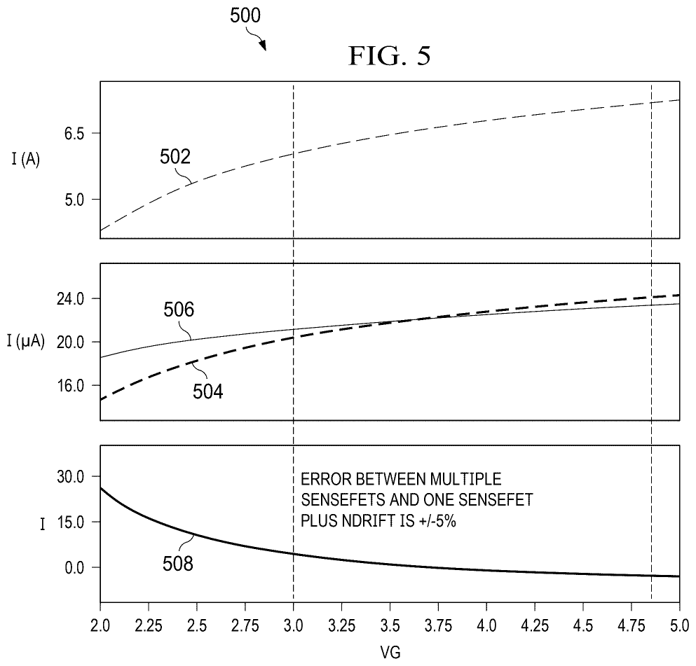

The combination of the second transistor 106 and the Ndrift resistors 108-114 provides current characteristics that are similar to the current characteristics of the first transistor 104, though possibly at a different scale (e.g., 1000 times smaller). If the Ndrift resistors 108-114 were implemented by conventional transistors (e.g., that include a backgate/source-connected body), each transistor would need to be implemented within its own isolation tank/well. However, by utilizing the Ndrift resistors 108-114 that do not include a backgate/source-connected body, the Ndrift resistors 108-114 can be implemented within a single well, which significantly reduces the physical space for implementing the components. Including the second transistor 106 at the incoming end of the series of components enables the second transistor 106 to provide the current regulation that a transistor network would provide. As illustrated in FIGS. 5-7, the difference between the current characteristics of a series transistor network and the transistor/resistor network illustrated in FIG. 1 is less than 5% for some example implementations (e.g., such an error can be acceptable for circuits that do not demand tight accuracies and where reduced die size is desirable).

The example comparator 116 compares the voltage at the drain of the first transistor 104 to the voltage at the drain of the second transistor 106 to output an indication (e.g., to indicate an overload or over current condition when the voltage at the first transistor 104 is greater than the voltage at the second transistor 106, to detect a current level in the load and output a signal indicating when the level is reached, etc.).

While the example circuit 100 utilizes the first transistor 106 in series with the Ndrift resistors 108-114 to provide overload detection and current feedback control, the structure of a transistor in series with one or more Ndrift resistors may be utilized in any type of circuit in which a series of transistors would be utilized. Furthermore, while four Ndrift resistors are included in the example of FIG. 1, any number of Ndrift resistors may be utilized in a circuit. For example, the number of Ndrift resistors may be selected to provide a desired ratio current ratio between a) the series-connected transistor and Ndrift resistors and b) a main/power FET.

In the example circuit 100, a first terminal of the load 102 is connected to a source (e.g., a voltage source not shown). A second terminal of the load 102 is connected to a positive terminal of the comparator 116 and a drain terminal of the first transistor 104. A gate of the first transistor 104 is connected to a voltage source labeled VGS. A source terminal of the first transistor 104 is connected to ground.

A drain terminal of the second transistor 106 is connected to a current reference powered by a voltage VCC. A gate terminal of the second transistor 106 is connected to VGS.

The Ndrift resistors 108-114 includes a first terminal that is similar to a gate terminal of a transistor. The first terminals of the Ndrift resistors 108-114 are connected to VGS. Connecting the first terminals of the Ndrift resistors 108-114 to VGS is fundamental to matching the voltage bias dependency of the Ndrift drain within the LDMOS to the voltage bias dependency of the Ndrift resistors 108-114. The Ndrift resistors 108-114 further include a second terminal and a third terminal that is internally coupled to a first end and a second end of the Ndrift resistance. The second terminal of the first Ndrift resistor 108 is connected to the source of the second transistor 106 and the third terminal of the first Ndrift resistor 108 is connected to the second terminal of the second Ndrift resistor 110. The third terminal of the second Ndrift resistor 110 is connected to the second terminal of the third Ndrift resistor 112. The third terminal of the third Ndrift resistor 112 is connected to the second terminal of the fourth Ndrift resistor 114. The third terminal of the fourth Ndrift resistor 114 is connected to ground.

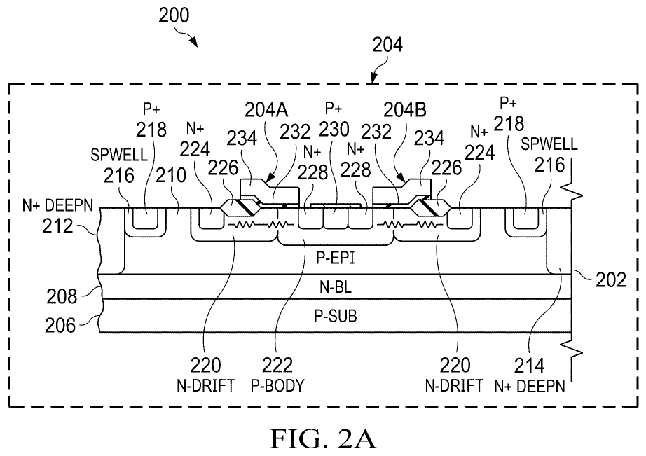

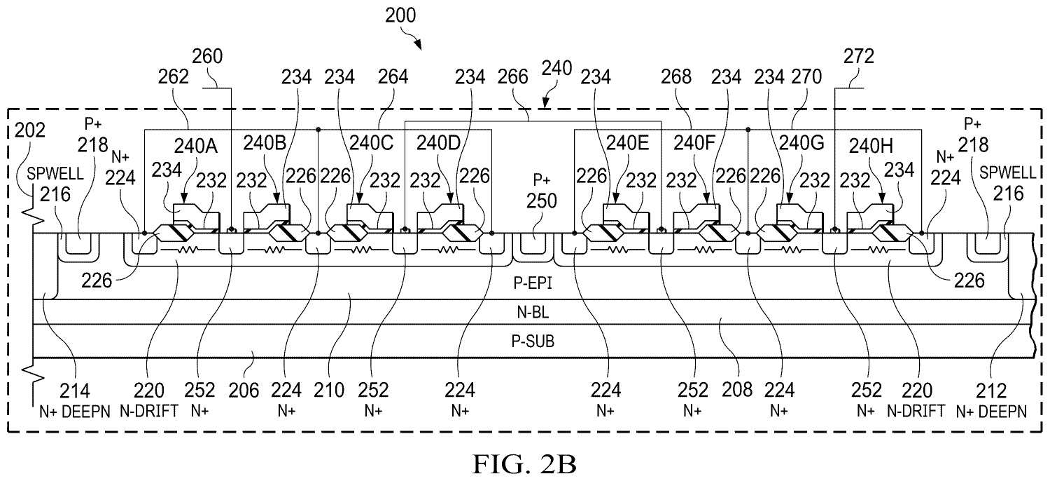

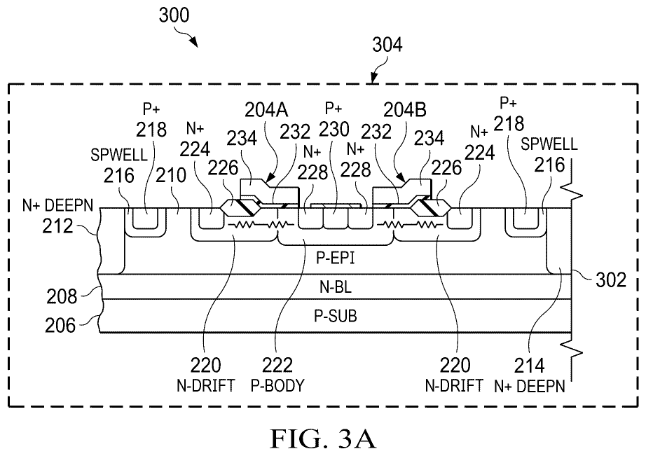

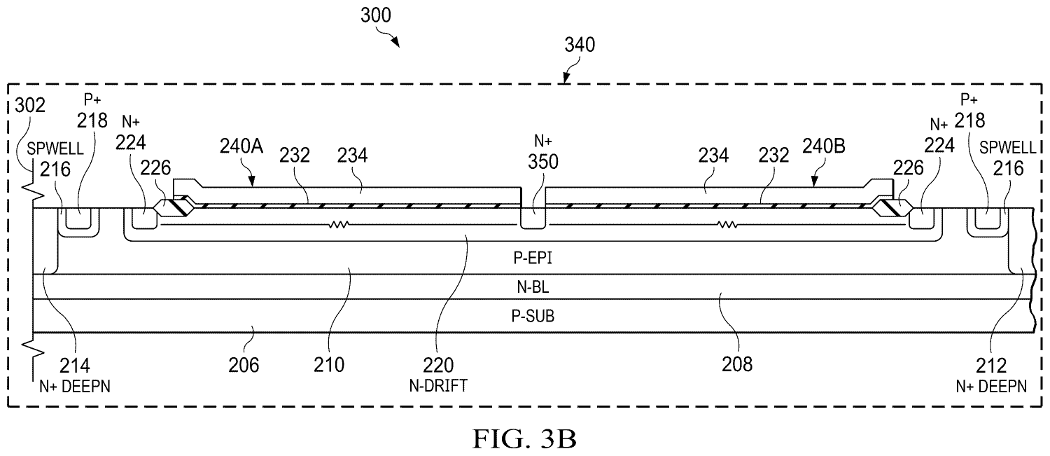

FIGS. 2A and 2B illustrate a cross-sectional view of an example integrated circuit 200. According to the illustrated example, the elements in FIG. 2A are coupled to the element in FIG. 2B at page break 202. In other examples, the elements in FIG. 2A may be implemented separately from the elements of FIG. 3B (e.g., separated by a distance, on a different die, on a different chip, etc.).

The elements in FIG. 2A implement a pair of LDMOS transistors 204. The example pair of LDMOS transistors 204 includes a positive doped sublayer 206, on which is layered a negative doped buried layer 208, on which is layered a positively doped epitaxial layer 210. A first negatively doped deep well 212 and a second negatively doped deep well 214 a formed in the epitaxial layer 210 and abut the buried layer 208. The first deep well 212 and the second deep well 214 provide an isolation tank/well between them. A first positively doped shallow well 216 is formed in the epitaxial layer 210 (e.g., the first positively doped shallow well 216 may abut the first deep well 212, may be near the first deep well 212, etc.). A second positively doped shallow well 218 is formed in the epitaxial layer 210 (e.g., the second posibitlvey-doped shallow well 218 may abut the second deep well 214, may be near the second deep well 214, etc.).

The pair of LDMOS transistors 204 include mirrored elements (one set of elements to form a first LDMOS 204A on the left and one set of elements to form a second LDMOS 204B on the right) and, thus, are labeled with matching reference numbers and described one time. A negatively doped drift region 220 is formed in the epitaxial layer 210 and abuts a positive doped body 222. A first negatively doped region 224 is formed in the drift region 220 to provide a transistor drain. A field oxide 226 is deposited on the drift region 220. A second negatively doped region 228 is formed within the body 222 to provide a transistor source. A positively doped region 230 is formed within the body 222 between the two second negatively doped regions 228. The transistor source is coupled to the body 222. A pad oxide 232 is layered on the field oxide 226, the drift region 220, and the body 222 and abuts the second negatively doped region 228. A polysilicon layer 234 is layered on the pad oxide 232 to form a transistor gate electrode (e.g., a polysilicon gate electrode). The pad oxide 232 is drawn to illustrate the gate active area; that is from source to field oxide 226. In processing, the pad oxide 232, which is the main gate area, may transition to the field oxide 232 as a contiguous geometry.

While FIG. 2A includes an example implementation of a pair of LDMOS transistors 204, the integrated circuit 200 could include any other implementation of an LDMOS transistor, any other type of transistor, and any number of transistors (e.g., a single transistor).

The elements in FIG. 2B implement a set 240 of eight Ndrift resistors 240A-H. The circuitry in FIG. 2B includes many of the same components as the circuitry in FIG. 2A and, thus, like elements of FIG. 2B are labeled with the same reference numbers as the elements in FIG. 2A and are not further described herein. The Ndrift resistors 240A-H of FIG. 2B do not include the positively-doped body 222 and the components included therein and do not include the second negatively-doped region 228 that are included in each of the pair of LDMOS transistors 204. Instead, the Ndrift resistors 240A-H include a single negatively doped region 252 with each pair of Ndrift resistors 240A/B, 240 C/D, 240 E/F, 240 G/H. An additional positively doped shallow well is included between each group of four Ndrift resistors 240 A-D and 240 E-H.

The Ndrift resistors 240 A-H may be utilized to implement the Ndrift resistors 108-114 of FIG. 1. For example, the Ndrift resistor 240A may implement the Ndrift resistor 108, the Ndrift resistor 240B may implement the Ndrift resistor 110, the Ndrift resistor 240C may implement the Ndrift resistor 112, and the Ndrift resistor 240D may implement the Ndrift resistor 114. In particular, according to the example of FIG. 2A, the source terminal of the transistor 106, which may be implemented by the transistor 204 of FIG. 2A, is coupled to single negatively doped region 252 of the Ndrift resistors 240A/B, the first negatively doped region 224 of the Ndrift resistor 240A is coupled to the first negatively doped region 224 of the Ndrift resistor 240B. The first negatively doped region 224 of the Ndrift resistor 240B is then coupled to the first negatively doped region 224 of Ndrift resistor 240C. The single negatively doped region of the Ndrift resistors 240 C/D is coupled to ground. Thus, according to this example, the Ndrift resistors 240 A-D are coupled in series to implement the series connection of the Ndrift resistors 108-114 of FIG. 1. While FIG. 1 utilizes four resistors as an equivalent of four transistors and FIG. 2B includes components for eight resistors as an equivalent of eight transistors, a circuit can be made with any number of Ndrift resistors (e.g., 2, 10, 12, 16, etc.). The more Ndrift resistors that are included in an isolation tank/well the more reduction in die area that can be accomplished as compared with conventional transistors.

An example interconnection of the Ndrift resistors 240 A-D in series is illustrated in FIG. 2B by lines 260-272. For example, the line 260 may be connected to one end of the series (e.g., the source of the transistor 106 of FIG. 1). Then, the series resistances proceed through the line 262, the line 264, the line 266, the line 268, the line 270, and the line 272 to provide an equivalent of eight transistors of resistance. For example, the open end of line 272 may be coupled to ground as illustrated in FIG. 1.

FIGS. 3A and 3B illustrate a cross-sectional view of another example integrated circuit 300. According to the illustrated example, the elements in FIG. 3A are coupled to the element in FIG. 3B at page break 302. In other examples, the elements in FIG. 3A may be implemented separately from the elements of FIG. 3B (e.g., separated by a distance, on a different die, on a different chip, etc.).

The elements in FIG. 3A implement a pair of LDMOS transistors 304. The example implementation of the transistors 304 is the same as the implementations of the transistors 204 and, thus, are not described further herein.

The elements in FIG. 3B implement a pair 340 of Ndrift resistors 340A, 340B. The circuitry in FIG. 3B includes many of the same components as the circuitry in FIGS. 2A, 2B, and 3A and, thus, like elements of FIG. 3B are labeled with the same reference numbers as the elements in FIGS. 2A, 2B, and 3A and are not further described herein. The example implementation of the pair 340 of Ndrift resistors 340A, 340B provides an equivalent resistance to the eight Ndrift resistors 240 A-H by expanding the drift region 220 to be four times as long as the drift region 220 of FIG. 2A. Accordingly, the Ndrift resistor 340A provides an equivalent resistance to four of the Ndrift resistors (e.g., 240 A-D) and the Ndrift resistor 340B provides an equivalent resistance to four of the Ndrift resistors (e.g., 240 E-H). The configuration constructed in FIG. 3B achieves further reduction of die size by eliminating several of the intermediate layers.

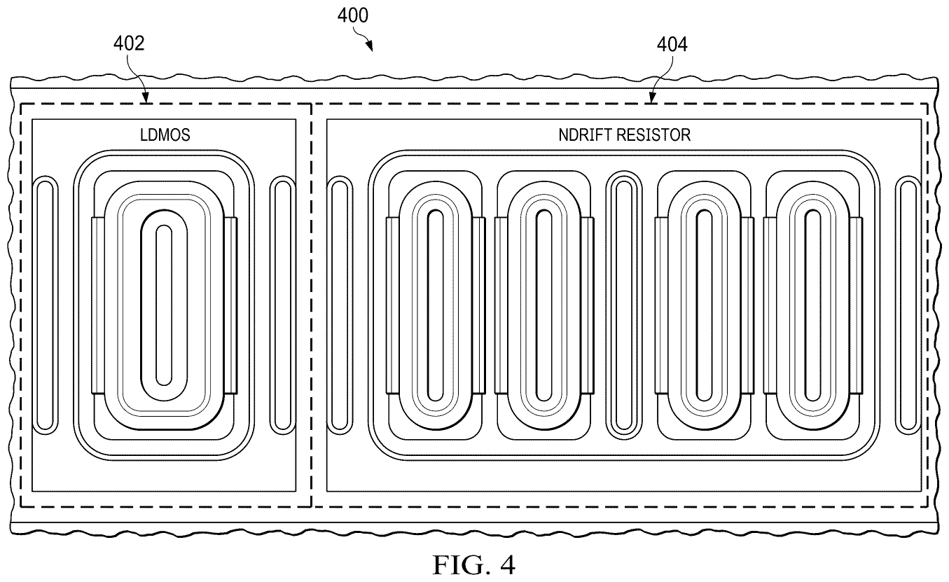

FIG. 4 is a top view of a die 400 including a first isolation tank 402 containing an LDMOS transistor and a second isolation tank 404 containing four pairs of Ndrift resistors. For example, the four pairs of Ndrift resistors in the second isolation tank 404 may be the four pairs of Ndrift resistors 240 A-H of FIG. 2A. Because the Ndrift resistors are not implemented as full transistors including source-connected bodies, they can be included in a single isolation tank without the sources shorting with each other. Accordingly, the space on the die required to implement the components is reduced as compared with full transistors.

FIG. 5 is a chart 500 illustrating measured current flow through a main transistor and a sensing transistor circuit implemented according to the circuitry described herein (e.g., as shown in FIGS. 2A/B and/or 3A/3B) for a gate voltage between 2 volts and 5 volts. As shown in FIG. 5, for an example main current flow 502, a sense circuitry implemented by transistors (e.g., 5 transistors) would have an example current flow 504. The ratio between 502 and 506 may remain constant across the gate voltage range, since the transistors (main and sense) may be constructed in the same way. When implementing the sense circuitry using a FET in series with one or more Ndrift resistors, the current flow 506 is measured at the sensing circuitry, which translates to an error 508. Within an acceptable range of gate voltage operation, such as between 3V and 5V, the error is below 5% and is a desirable tradeoff to reduce the physical die space that would have been needed to implement a full transistor implementation. It is possible to further optimize the circuit with Ndrift sense resistors, by slightly changing the length of Ndrift resistors and/or the size of transistor 106 in order to reduce the error further.

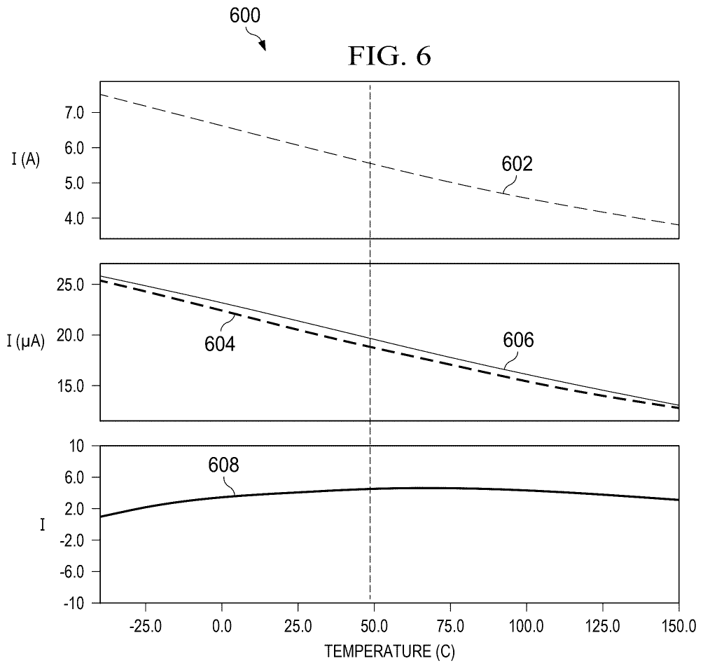

FIG. 6 is a chart 600 illustrating measured current flow through a main transistor and a sensing transistor circuit implemented according to the circuitry described herein (e.g., as shown in FIGS. 2A/B and/or 3A/3B) for a gate voltage of 3 volts over a range of temperatures. As shown in FIG. 6, for an example main current flow 602, a sense circuitry implemented by transistors (e.g., 6 transistors) would have an example current flow 604. The ratio between 602 and 606 may remain constant across the gate voltage range, since the transistors (main and sense) may be constructed in the same way. When implementing the sense circuitry using a FET in series with one or more Ndrift resistors, the current flow 606 is measured at the sensing circuitry, which translates to an error 608. The error is below 6% and is a desirable tradeoff to reduce the physical die space that would have been needed to implement a full transistor implementation.

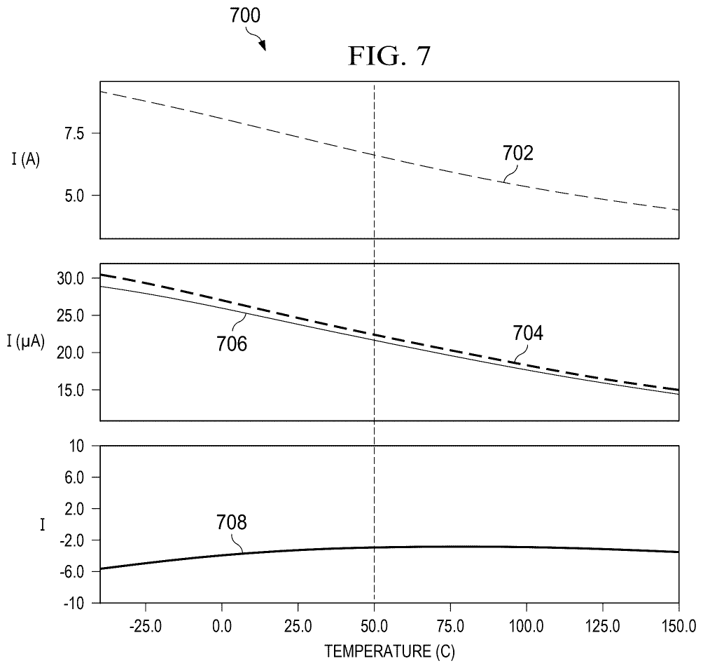

FIG. 7 is a chart 700 illustrating measured current flow through a main transistor and a sensing transistor circuit implemented according to the circuitry described herein (e.g., as shown in FIGS. 2A/B and/or 3A/3B) for a gate voltage of 5 volts over a range of temperatures. As shown in FIG. 7, for an example main current flow 702, a sense circuitry implemented by transistors (e.g., 7 transistors) would have an example current flow 704. The ratio between 702 and 706 may remain constant across the gate voltage range, since the transistors (main and sense) may be constructed in the same way. When implementing the sense circuitry using a FET in series with one or more Ndrift resistors, the current flow 706 is measured at the sensing circuitry, which translates to an error 708. The error is below 7% and is a desirable tradeoff to reduce the physical die space that would have been needed to implement a full transistor implementation.

In the examples described herein, the transistors and Ndrift resistors are based on n-channel metal-oxide semiconductor implementation. Alternatively, the transistors and/or Ndrift resistors may be implemented according to p-channel architectures.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing at least one of a semiconductor device (e.g., a transistor), a semiconductor die containing a semiconductor device, or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. Semiconductor devices are often used in orientation different than their orientation during fabrication. Thus, when referring to one of or a combination of a semiconductor device (e.g., a transistor), a semiconductor die containing a semiconductor device, or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for case of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

From the foregoing, it will be appreciated that example systems, apparatus and articles of manufacture have been described that implement Ndrift resistors and/or utilize such Ndrift resistors in circuitry in place of transistors. Described systems, apparatus, articles of manufacture, and methods improve upon transistor circuitry by enabling multiple semiconductors to be implemented within a single isolation tank, reducing the physical space required to implement such circuitry.

What is claimed is:

1. An apparatus comprising:
a metal-oxide-semiconductor (MOS);
a first negative well;
a second negative well, wherein the MOS is between the first negative well and the second negative well;
a third negative well; and
at least four negatively doped drift (Ndrift) regions, wherein the at least four Ndrift regions are between the second negative well and the third negative well.

2. The apparatus of claim 1, wherein the MOS is a laterally-diffused metal-oxide-semiconductor.

3. The apparatus of claim 1, wherein the first negative well, the second negative well, and the third negative well are deep wells.

4. The apparatus of claim 1, wherein the MOS includes a positively doped body.

5. The apparatus of claim 1, wherein the apparatus does not include a body between the second negative well and the third negative well.

6. The apparatus of claim 1, wherein the apparatus does not include a positive doped body region between the second negative well and the third negative well.

7. The apparatus of claim 1, further including:
a first positively doped well;
a second positively doped well; and
a third positively doped well, wherein a first two of the at least four Ndrift regions are between the first positively doped well and the second positively doped well and a second two of the at least four Ndrift regions are between the second positively doped well and the third positively doped well.

8. The apparatus of claim 1, further including:
a first polysilicon gate electrode;
a second polysilicon gate electrode;
a third polysilicon gate electrode; and
a fourth polysilicon gate electrode.

9. The apparatus of claim 8, further including a:
a first negatively doped region within a first one of the at least four Ndrift regions;
a second negatively doped region within the first one of the at least four Ndrift regions; and
a third negatively doped region within the first one of the at least four Ndrift regions.

10. The apparatus of claim 9, wherein the first negatively doped region is coupled to the third negatively doped region.

11. An apparatus comprising:
an epitaxial layer;
a negatively doped drift (Ndrift) region in the epitaxial layer;
a first negatively doped region in the Ndrift region;
a second negatively doped region in the Ndrift region;
a first field oxide in the Ndrift region and coupled to the first negatively doped region;
a first pad oxide on the first field oxide and the Ndrift region and in contact with the second negatively doped region; and
a first isolation layer on the Ndrift region and in contact with the second negatively doped region.

12. The apparatus of claim 11, further including:
a substrate; and
a buried layer on the substrate, wherein the epitaxial layer is on the substrate.

13. The apparatus of claim 12, wherein the epitaxial layer is positively, the buried layer is negatively doped, and the substrate is positively doped.

14. The apparatus of claim 12, further including:
a first negatively doped well through the epitaxial layer and in contact with the buried layer; and
a second negatively doped well through the epitaxial layer and in contact with the buried layer.

15. The apparatus of claim 14, wherein the Ndrift region is between the first negatively doped well and the second negatively doped well.

16. The apparatus of claim 11, further including:
a first shallow positively doped well in the epitaxial layer; and
a second shallow positively doped well in the epitaxial layer.

17. The apparatus of claim 11, further including:
a third negatively doped region in the Ndrift region;
a second field oxide in the Ndrift region and coupled to the third negatively doped region, wherein a second pad oxide is on the second field oxide;
a first polysilicon gate layer on the first isolation layer; and
a second polysilicon gate layer on a second isolation layer.

18. An apparatus comprising:
a first laterally-diffused metal-oxide semiconductor (LDMOS) having a gate, a source, and a drain;
a second LDMOS having a gate coupled to the gate of the first LDMOS and a source; and
a first negatively doped drift resistor coupled to the source of the second LDMOS.

19. The apparatus of claim 18, further including a second negatively doped drift resistor coupled to the first negatively doped drift resistor.

20. The apparatus of claim 19, wherein the source of the first LDMOS and the second negatively doped drift resistor are coupled to ground.
